(19) United States
(12) Patent Application Publication
(10) Pub. No.: US 2018/0286815 A1
(43) Pub. Date: Oct. 4, 2018

(54) SHIELDING SOLUTIONS FOR DIRECT CHIP ATTACH CONNECTIVITY MODULE PACKAGE STRUCTURES HAVING SHIELDING STRUCTURES ATTACHED TO PACKAGE STRUCTURES

(71) Applicant: Intel IP Corporation, Santa Clara, CA (US)

(72) Inventors: Quan Qi, Beaverton, OR (US); Carlton E. Hanna, Santa Clara, CA (US)

(73) Assignee: Intel IP Corporation, Santa Clara, CA (US)

(21) Appl. No.: 15/474,251

(22) Filed: Mar. 30, 2017

(51) Int. Cl. H01L 23/552; H01L 23/60; H01L 23/498; H01L 23/00; H01L 21/3205; H01L 21/285

(52) U.S. Cl. CPC H01L 23/552; H01L 23/60; H01L 23/49838; H01L 23/49827; H01L 23/49822; H01L 2924/19105; H01L 21/32051; H01L 21/2855; H01L 2224/16227; H01L 2924/3025; H01L 24/17

(57) ABSTRACT

Methods of forming microelectronic package structures, and structures formed thereby, are described. Those methods/structures may include a shielding structure disposed on a surface of a package structure, wherein the shielding structure comprises a film; a conductive material disposed on a surface of the film; and a plurality of conductive bars, wherein each individual conductive bar of the plurality of conductive bars is disposed through the film, and at least a portion of the plurality of conductive bars is physically coupled with grounding traces disposed on the surface of the package structure.

### BACKGROUND

Connectivity solutions for microelectronic package structures may utilize printed circuit board (PCB) technologies, as well as substrate based silicon in package (SiP) solutions/technologies. PCB based module solutions can provide a significant cost advantage, particularly for mainstream high volume manufacturing (HVM) connectivity products.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIGS. 1a-1b represent cross-sectional views of structures according to embodiments, FIGS. 1c-1e. represent top views of structures according to embodiments, FIGS. 1f-1i represent cross-sectional views of structures according to embodiments.

FIGS. 2a-2b represent a top view and a cross-sectional view, respectively, of structures according to embodiments.

FIG. 3 represents a flow chart of a method according to embodiments.

FIG. 4 represents a schematic of a computing system according to embodiments.

FIG. 5 represents a schematic of a computing device according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between an electrical component, such a an integrated circuit (IC) die, and a next-level component to which an IC package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die may include a front-side and an opposing back-side. In some embodiments, the front-side may be referred to as the “active surface” of the die. A number of interconnects may extend from the die's front-side to the underlying substrate, and these interconnects may electrically couple the die and substrate. In some cases a die may be directly coupled to a board, such as a motherboard. Interconnects/traces may comprise any type of structure and materials capable of providing electrical communication between a die and substrate/board. In some one embodiment, a die may be disposed on a substrate in a flip-chip arrangement. In an embodiment interconnects comprises an electrically conductive terminal on a die (e.g., a pad, bump, stud bump, column, pillar, or other suitable structure or combination of structures) and a corresponding electrically conductive terminal on the substrate (e.g., a pad, bump, stud bump, column, pillar, or other suitable structure or combination of structures).

Solder (e.g., in the form of balls or bumps) may be disposed on the terminals of the substrate and/or die, and these terminals may then be joined using a solder reflow process. Of course, it should be understood that many other types of interconnects and materials are possible (e.g., wirebonds extending between a die and substrate). In some embodiments herein, a die may be coupled with a substrate by a number of interconnects in a flip-chip arrangement. However, in other embodiments, alternative structures and/or methods may be utilized to couple a die with a substrate.

Embodiments of methods of forming packaging structures, including methods of forming shielding structures for connectivity modules, such as for partially molded direct chip attach die (DCA) connectivity solutions/structures, are described. Those methods/structures may include a shielding structure disposed on a surface of a package structure, wherein the shielding structure comprises a film; a conductive material disposed on a surface of the film; and a plurality of conductive bars, wherein each individual conductive bar of the plurality of conductive bars is disposed through the film, and at least a portion of the plurality of conductive bars is physically coupled with grounding traces disposed on the surface of the package structure. The embodiments herein enable the formation of conformal shielding solutions with low Z height and enhanced interference minimization.

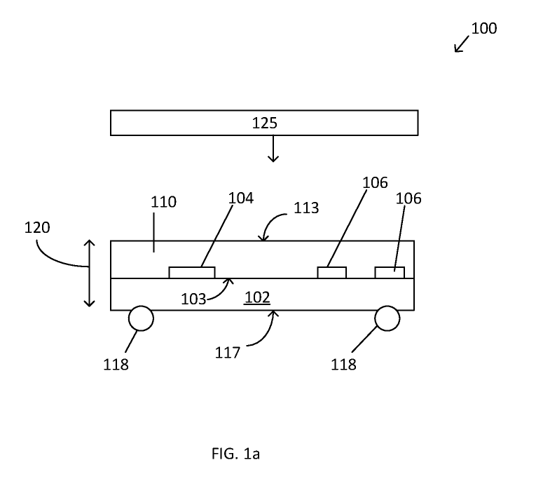

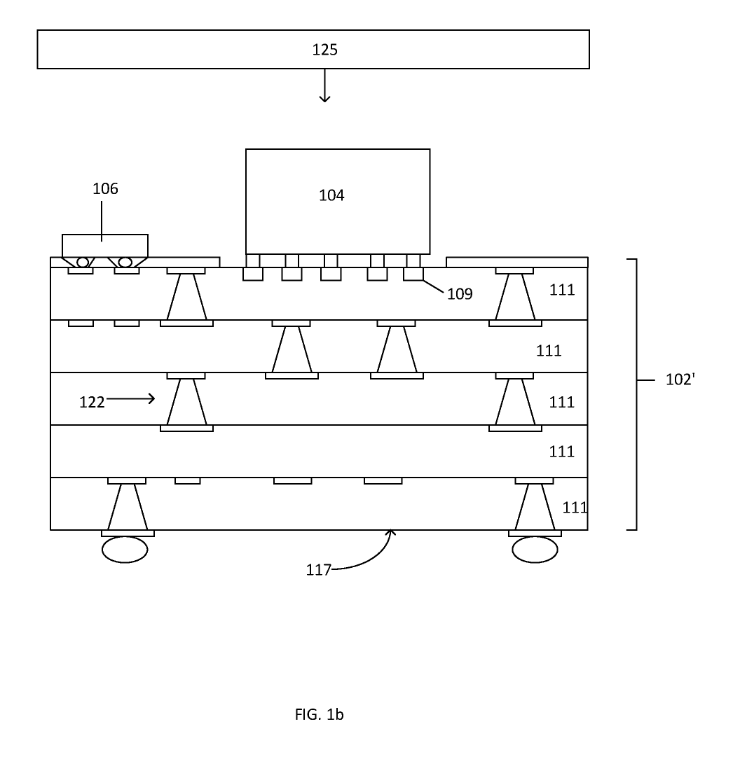

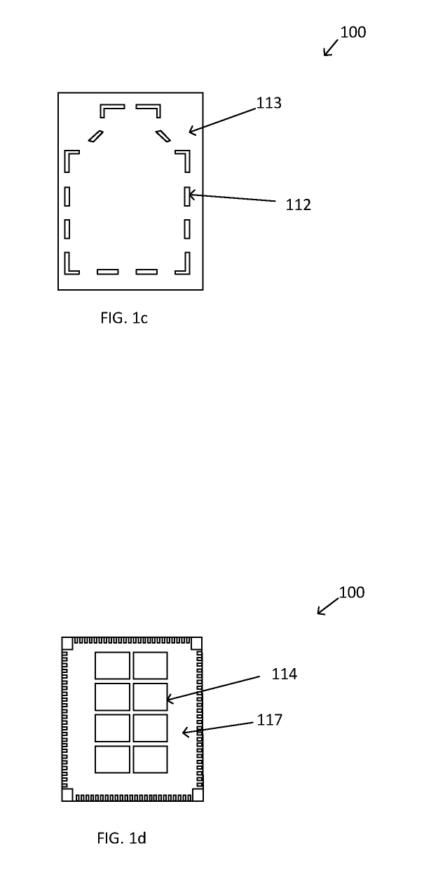

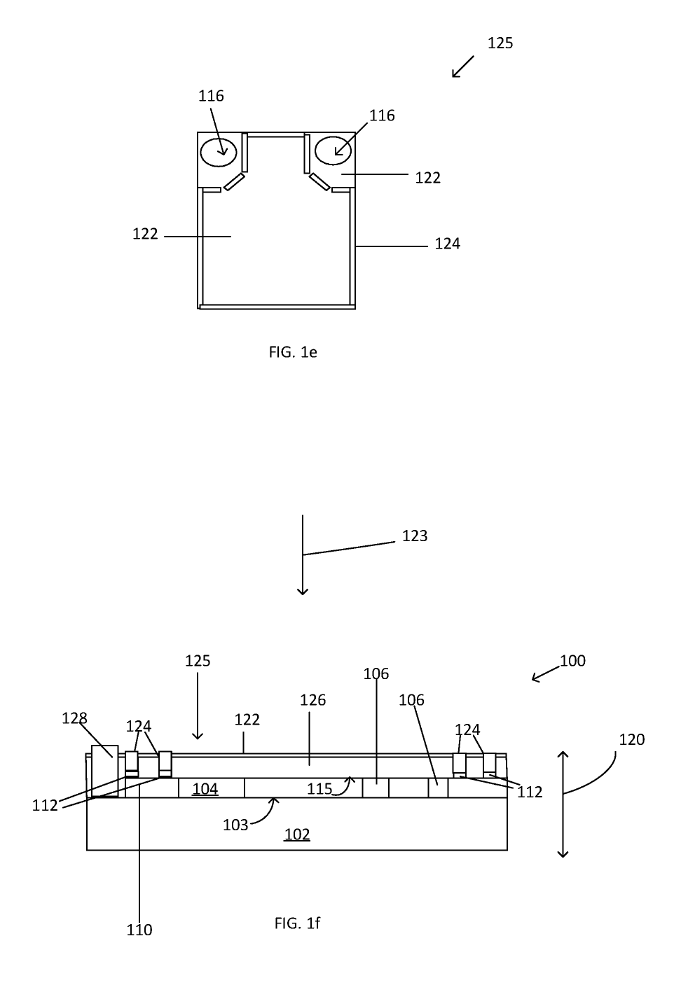

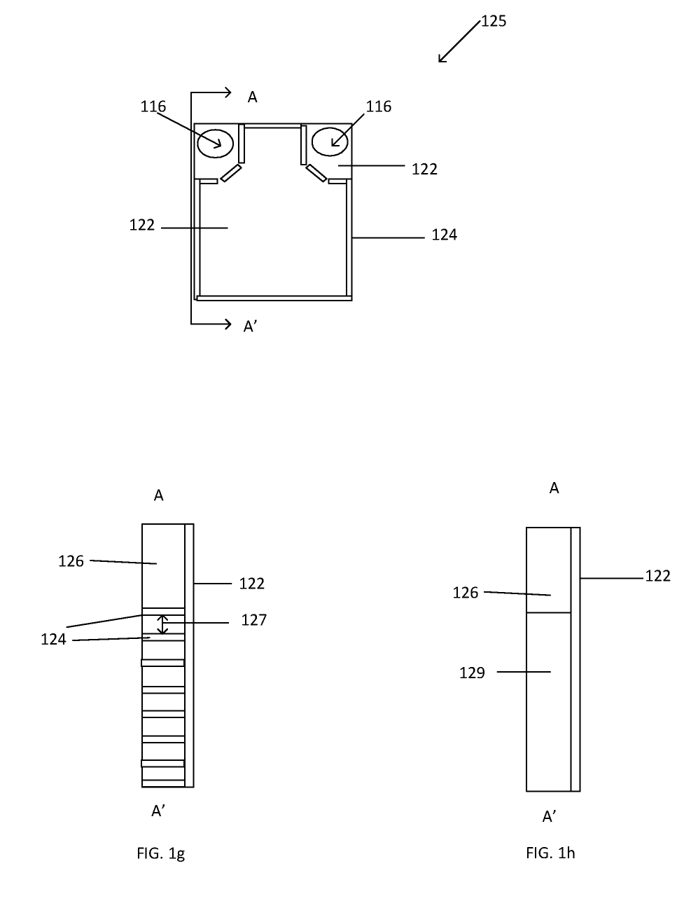

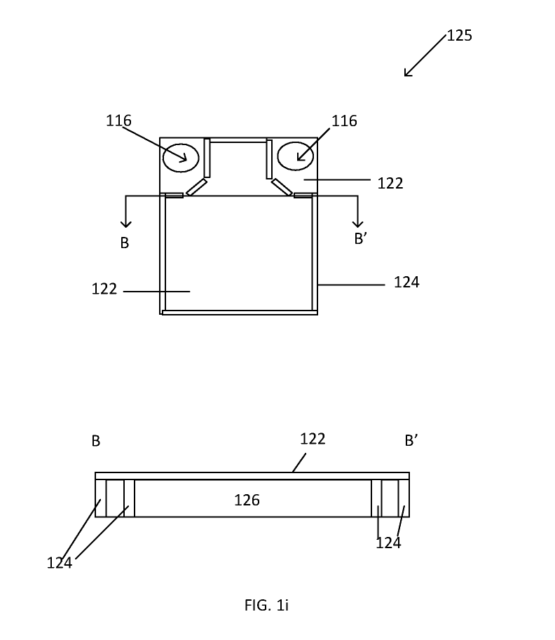

The Figures herein illustrate embodiments of methods of fabricating package structures comprising electromagnetic interference (EMI) shielding structures, and structures formed thereby. In FIG. 1a (cross-sectional view), a portion of a package structure 100, such as a direct chip attach (DCA) connectivity package structure/module 100, is shown. Any other type of suitable package structures 100 may be employed with the embodiments of the shielding structures described herein, depending upon the particular design requirements. In an embodiment, a substrate 102, may comprise a board, such as a printed circuit board (PCB board), for example, and in other embodiments, the substrate 102 may comprise a high density PCB, wherein routing/interconnect lines within the substrate 102 may comprise about 40/40 micron trace/spacing and/or line/space (L/S) design rules and below. In another embodiment, the substrate 102 may comprise about 25/25 micron L/S dimensions.

In another embodiment, the substrate 102 may comprise an embedded trace PCB (ETP) (FIG. 1b, cross-sectional view). The ETP substrate 102 may comprise embedded conductive traces 109 (as well as various conductive contact and via structures 122, for example) disposed in a dielectric material 111, wherein a die/device 104 may be physically and electrically coupled to the embedded traces 109, and at least one component 106 may be disposed and electrically coupled to the embedded traces 109 on the first substrate 102. A shielding structure 125 (to be described in more detail subsequently herein) may be attached to top surfaces of the at least one component 106 and die 104, in an embodiment. The at least one component may comprise a surface mount technology (SMT) component, in an embodiment. The embedded traces 109 may comprise trace/spacing (L/S) of about 12/12 microns to about 7/7 microns, in some embodiments. Thus, the employment of an ETP substrate as a substrate 102 in the package structures 100 described herein serves to improve routing capacity of the packages structures/modules, and ensures efficient routing with reduced layer counts, which reduces a Z-height 120 of the module 100, as well as accommodating surface mount technology assembly/components 106, molding underfill and electromagnetic interference (EMI) shielding.

In an embodiment (referring back to FIG. 1a), a die/device 104, such as a microelectronic die, may be disposed/placed on a top surface 103 of the substrate 102. In an embodiment, the die 104 may comprise any type of microelectronic device, including devices comprising wireless capabilities, such as but not limited to a microprocessor, a graphics processor, a signal processor, a network processor, a chipset, etc. In one embodiment, the die 104 comprises a system on a chip (SOC) having multiple functional units (e.g., one or more processing units, one or more graphics units, one or more communications units, one or more signal processing units, one or more security units, etc.). However, it should be understood that the disclosed embodiments are not limited to any particular type or class of die/devices. The device/die 104 may be electrically and physically coupled with the substrate/board 102 by solder balls/conductive structures (not shown). In an embodiment, more than one die 104 may be disposed on the top surface 103 of the substrate 102. In an embodiment, the die 104 may comprise a bare die 104.

At least one component 106 may be disposed/placed adjacent the die 104 on the top surface of the substrate 102. The at least one component 106 may comprise such components as a die-side capacitor, an inductor, a component comprising a crystal oscillator, and/or a surface mount technology component, for example. In an embodiment, the at least one component 106 may comprise any other suitable type of circuit elements/devices, such as a resistor, for example, according to the particular design requirements

A molding material 110 may optionally be disposed/placed on the die 104 and on the at least one component 106. The molding material 110 may be disposed on the top surface 103 of the substrate 102. The molding material 110 may comprise an epoxy material in an embodiment, or may comprise any other suitable material as required by the particular application. In an embodiment, the molding material 110 may comprise a molding underfill material (MUF), wherein the die 104 and the at least one component 106 may be fully embedded within the molding material 110. In an embodiment, the package structure 100 may comprise a top surface 113, which may be located on a top surface of the molding material 110, in an embodiment. The package structure 100 may comprise a bottom surface 117. A shielding structure 125 (to be subsequently described herein, such as is depicted in FIG. 1e, for example) may be placed/attached onto the top surface 113, in an embodiment.

The top surface 113 of the package structure 100 may comprise grounding traces 112 (FIG. 1c, top view), onto which the shielding structure 125 may be attached, in an embodiment. In an embodiment, the grounding traces 112 may be located in a peripheral portion of the top surface of the package structure 100. The bottom surface 117 of the package structure 100 may comprise a communication structure 114, such as an antenna structure, for example (FIG. 1d, bottom view). The location of communication structure 114 may vary depending upon the design requirements of the particular application. For example, the communication structure 114 may be located on the top surface 113 of the package structure, in some embodiments, and in other embodiments, the communication structure 114 may be located on a second substrate (not shown) that may be coupled with the first substrate 102. In other embodiments, the communication structure 114 may be disposed on a substrate, such as on the substrate 102 of FIG. 1a. The communication structure 114 may serve to allow for wireless communication between the package structure 100 and external and/or internal components, in an embodiment

A shielding structure 125, which may comprise an EMI shielding structure for a package structure, such as package structure 100, may be formed/provided onto the top 113 of the package structure 100, according to embodiments included herein (FIG. 1e). The shielding structure 125 may comprise a grounding rim structure 124, which may comprise a conductive material, such as copper for example, and may comprise a sputtered metallic material in an embodiment. The grounding rim structure 124 may be located in a peripheral portion of the shielding structure 125. In an embodiment, the grounding rim 124 may further comprise/may be impregnated with, conductive bars/and or meshes, which will be described further herein. The shielding structure 125 may further comprise a conductive coating 122, such as a copper material 122, in an embodiment. The conductive coating 122 may comprise an EMI coating, and may comprise openings 116, which may be customized in shape and location to accommodate connector/communication structures that may be present on a package structure, such as the package structure 100 of FIG. 1a, for example.

The shielding structure 125 may be placed onto the top surface 113 of the package structure 100 by utilizing a process 123, such as a batch process, for example, wherein the shielding structure 125 may be formed to overlay a package structure, for example (FIG. 1f). Any suitable process 123 may be employed to form/place the shielding structure 125 onto the package structure 100. In an embodiment, a communication/connection structure 128 that may be disposed on the package structure 100, may be disposed within the shield structure 125 openings 116 of FIG. 1e. The grounding rim 124 may extend through a film 126, which may comprise a polymer material, in an embodiment. The ground rim extensions 124 may be electrically and physically coupled, and may be directly disposed upon in some cases, grounding traces 112 that may be disposed on the package structure 100.

A portion of a plurality of the ground rim extensions 124 of the shielding structure 125 may be adjacent to the connection structure(s) 128, in an embodiment. A top surface 115 of the structure 100 may be a top surface of the mold material 110, or in other embodiments, the package structure 100 may not comprise the mold material, but may comprise another suitable material, such as a dielectric material on the substrate 102, for example. In some embodiments, the components 106 and die 104 may be planar with the top surface 115 of the mold material 110, wherein portions of the ground rim 124 and portions of the film 126 may be directly disposed on at least portions of the at least one component 106 and on the die 104. In an embodiment, the film 126 may be adhesive and bondable to components/die disposed on the substrate 102, and can be applied to the package structure 100 by the use of a vacuum process, for example. In an embodiment, the EMI coating 122 of the shield structure 125 is capable of filtering undesired frequencies, such as deleterious RF frequencies, from the package structure/module 100. In an embodiment, the openings 116 of FIG. 1e may act as venting holes, wherein during the placement process 123, such as during a lamination process, for example, air may escape through the openings 116. Thus, the openings allow for the avoidance of undesired bubbles that may form between the module 100 and the film 126 during placement processing 123.

The shielding structure 125 may be disposed on a top surface and on side surfaces of the molding material 110/top surface of the package structure 100, and may optionally be disposed on at least a portion of the top surface 103 of the substrate 102, in some embodiments. The shielding structure 125 may comprise a thickness of about 3 microns to about 7 microns, but may vary depending upon the particular application. In an embodiment, the shielding material 108 may reduce the Z height 120 of the package structure 100.

The shielding structure 125 may serve to protect/shield the module 100 from undesired EMI/radio frequency (RF) radiation/signals. In an embodiment, the first substrate 102 comprising the molding material 110, embedded die 104 and embedded components 106, and shielding material 108 may comprise a first portion 101 of the (DCA) connectivity module 100. In an embodiment, the first portion of the DCA connectivity module 100 may comprise a Z height 120. In an embodiment, the first substrate 102 of the first portion 101 of the module 100 may be utilized to support the routing needs & assembly requirements of surface mount (SMT) components, molding operations, as well as EMI shielding operations/processes. The DCA module may comprise a second substrate attached to the first substrate, in some embodiments.

FIGS. 1g-1h depict side views of the shielding structure 125 through points A-A′. In an embodiment, the ground rim 124 comprising bars are depicted as extending through the film 126 (FIG. 1g). In an embodiment, the terminal end portions of the ground rim bars 124 are disposed on a portion of the EMI coating 122, and on a portion of structures disposed on the substrate 102 of the package structure, such as on SMT components, grounding traces 112 and/or die 104, respectively, for example. In an embodiment, space between individual bars 124 may be separated by a spacing 127, wherein the spacing distance 127 may be tuned/adjusted to screen out/filter a particular frequency, in order to eliminate unwanted frequencies from the module/package substrate 100.

FIG. 1h depicts an embodiment wherein the extension of the grounding rim 124 through the film 126 may comprise a solid plate 129, that may extend through the film 126, and may be directly disposed on the EMI coating 122, and may be directly disposed on grounding traces 112, components 106 and/or die 104 disposed on the package structure 100. In another embodiment, FIG. 1i depicts a side view of the shielding structure 125 through points B-B′. In an embodiment, the ground rim 124 comprising bars is depicted as extending through the film 126. In an embodiment, a first terminal end portion of the ground rim bars 124 is disposed on a portion of the EMI coating 122, and a second terminal end portion of the ground rim extensions 124 may be disposed on structures disposed on the substrate 102 of the package structure, such as disposed on SMT components, grounding traces 112, molding material, dielectric material, and/or die 104, for example.

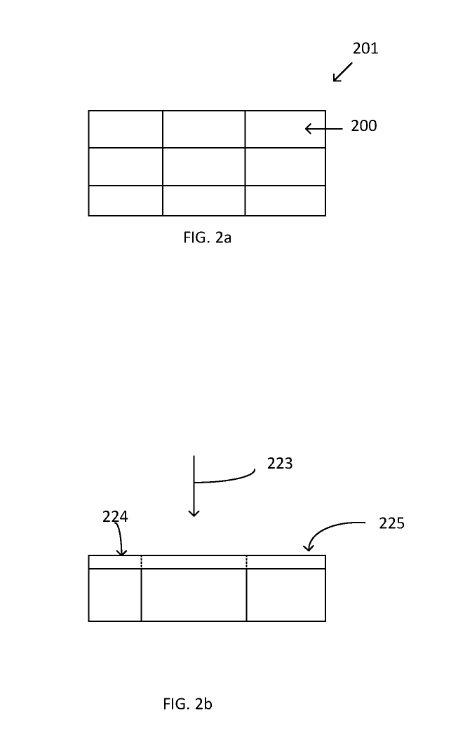

FIGS. 2a-2b depict a fabrication process, such as a batch fabrication process, for the placement/attachment of a shielding structure according to embodiments herein, onto a package structure/module. In an embodiment, a multipack/multi-panel structure 201 may be provided. The multipack structure 201 may comprise multiple portions of package structures 200, wherein the individual portions of the multi pack 201 may comprise any suitable type of package structures 200, and may comprise portions of DCA module structures 201, for example. An attachment process 223 may be employed to attach a multi panel shielding structure 225 to the multi-pack structure 201. The multi panel shielding structure 225 may comprise multiple portions 224, wherein each portion may comprise an EMI coating disposed on a film, and a grounding rim comprising the extension bars, as well as openings for connector structures, similar to the shielding structure 125 of FIG. 1e, for example. In an embodiment, the multi pack comprising the shield structure(s) 225 may be singulated after the attachment process 223 has been performed.

The various embodiments of the package assemblies/structures describe herein provide an improvement over typical in EMI shielding solutions, such as metal lid EMI structures of the prior art. The shielding structures of the embodiments herein provide shielding to effectively eliminate unwanted signals, minimize interference among different wireless signals, reduce overall form factors, especially in module Z height or thickness. The embodiments herein are compatible with high volume manufacturing batch processing, and provide physical protection for connectivity modules, especially in the case of direct DCA wireless modules, where bare silicon may be utilized.

The embodiments herein provide a film based shielding solution which contains impregnated metal fences to act as an effective Faraday Cage. The films of the embodiments herein can be either adhesive in nature or can be applied in a vacuum environment to ensure good adhesion with passivation materials that may be disposed on a top layer of a PCB module. The film comprises a sufficient thickness of an EMI coating layer on a back surface to ensure EMI filtering performance. The size of the shielding film can be made to fit a particular module size (ex. a solder down module may be used). The shielding film comprises openings to accommodate connector structures disposed on a module, which allow air to escape to avoid unwanted bubbles formation. The Faraday cage shielding can possess metal a plurality of bars/stick/needles or other metal inserts (into the film matrix) to provide effective blockage of EMI energy from escaping sideways. Furthermore these metal inserts may be in close contact with grounding traces on PCB modules.

The embodiments provide a conformal shielding solution that possesses a low z height, and also provides mechanical protection to all devices underneath the shielding. The embodiments are applicable with devices that are either already packaged or bare die. Moreover, since the shielding structures of the embodiments herein are conformal, improved isolation between different signals is enabled. the proposed solution is a batch process compatible solution and should help with the throughput in the HVM environment.

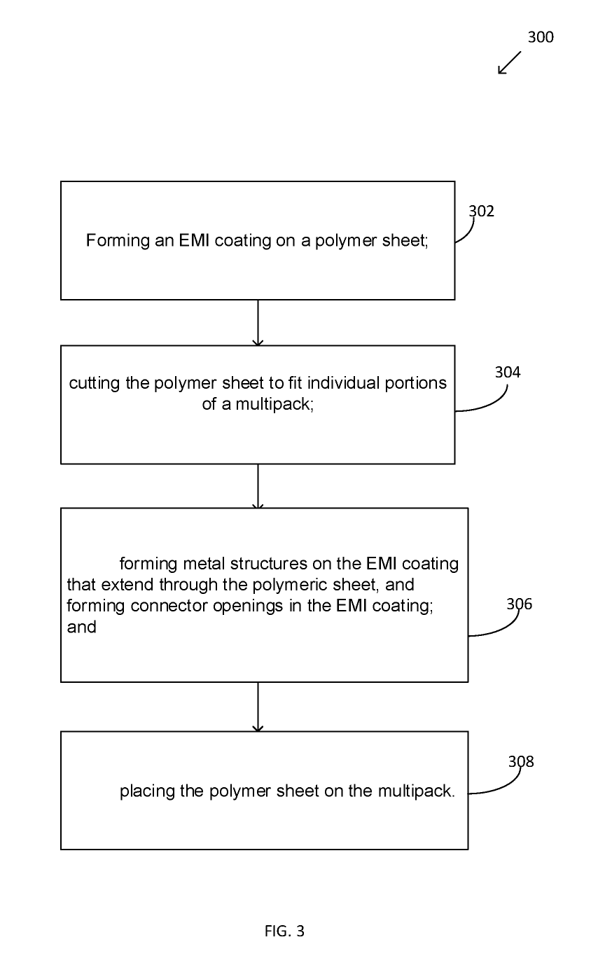

FIG. 3 depicts a method 300 of forming a shielding structure according to embodiments herein. At step 302, an EMI coating may be formed on a polymer sheet. The polymer sheet may be polymeric in nature with good adhesion to structures disposed on a module PCB. In an embodiment, the polymer can survive multiple lead free reflows. In an embodiment, a back side of the polymer sheet may comprise the EMI material. The EMI material may be formed by a sputtering process, and may comprise a conductive metal, such as copper, for example. At step 304 the polymer sheet may be cut to fit a multi panel size. At step 306 metal/conductive structures, such as metal bars and or metal plates, may be formed on the EMI coating that extend through the polymer sheet, and openings, such as connector openings, may be formed in the EMI coating.

The metal structures may be impregnated into the polymer film/sheet matrix, while ensuring good electrical contact between the metal structures with the EMI coating materials. The openings may be made in the EMI material with holes punched to fit antenna opening locations and connector shapes, which may comprise various shapes, depending upon the particular application. At step 308, the polymer sheet, which may comprise an EMI shielding structure, may be attached to the multi pack. In an embodiment, the film sheet may be attached/overlaid onto a multi pack and then the pack may be singulated. The attachment may be done adhesively or by a vacuum process. Connecting the EMI coating to the grounding traces with metal bars maintains a low Z height for a communication module.

The structures of the embodiments herein may be coupled with any suitable type of structures capable of providing electrical communications between a microelectronic device, such as a die, disposed in package structures, and a next-level component to which the package structures may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, the die(s) may be partially or fully embedded in a package structure.

The various embodiments of the package structures included herein may be used for system on a chip (SOC) products, and may find application in such devices as smart phones, notebooks, tablets, wearable devices and other electronic mobile devices. In various implementations, the package structures may be included in a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

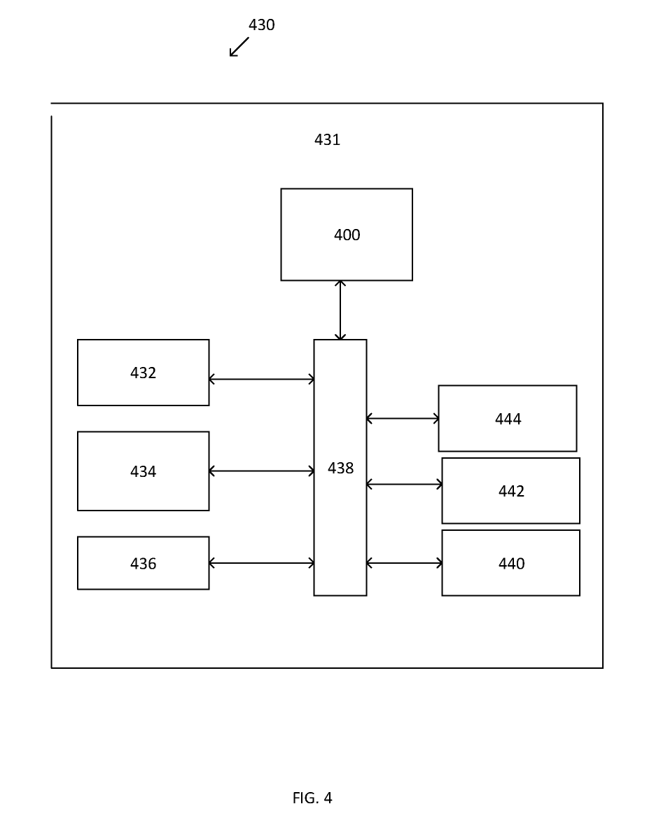

Turning now to FIG. 4, illustrated is a schematic of an embodiment of a portion of a computing system 430, including one or more of the modules/package structures 400 of the embodiments included herein. The module 400 may include any or all of the elements of the embodiments included herein as a part of the system 430.

In some embodiments, the system 430 includes a processing means such as one or more processors 432 coupled to one or more buses or interconnects, shown in general as bus 438. The processors 432 may comprise one or more physical processors and one or more logical processors. In some embodiments, the processors may include one or more general-purpose processors or special-processor processors.

The bus 438 may be a communication means for transmission of data. The bus 438 may be a single bus for shown for simplicity, but may represent multiple different interconnects or buses and the component connections to such interconnects or buses may vary. The bus 438 shown in FIG. 4 is an abstraction that represents any one or more separate physical buses, point-to-point connections, or both connected by appropriate bridges, adapters, or controllers. In some embodiments, the system 430 further comprises a random access memory (RAM) or other dynamic storage device or element as a main memory 334 for storing information and instructions to be executed by the processors 432. Main memory 434 may include, but is not limited to, dynamic random access memory (DRAM). The system 430 also may comprise one or more passive devices 436, such as capacitors and inductors, that may be installed on a board, such as a printed circuit board 331.

In some embodiments, the system 430 includes one or more transmitters or receivers 440 coupled to the bus 438. In some embodiments, the system 430 may include one or more antennae 444 (internal or external), such as dipole or monopole antennae, for the transmission and reception of data via wireless communication using a wireless transmitter, receiver, or both, and one or more ports 442 for the transmission and reception of data via wired communications. Wireless communication includes, but is not limited to, Wi-Fi, Bluetooth™, near field communication, and other wireless communication standards. In an embodiment at least one antenna may be included in the module 300, as described herein.

System 430 may comprise any type of computing system, such as, for example, a hand-held or mobile computing device (e.g., a cell phone, a smart phone, a mobile internet device, a music player, a tablet computer, a laptop computer, a nettop computer, etc.). However, the disclosed embodiments are not limited to hand-held and other mobile computing devices and these embodiments may find application in other types of computing systems, such as desk-top computers and servers.

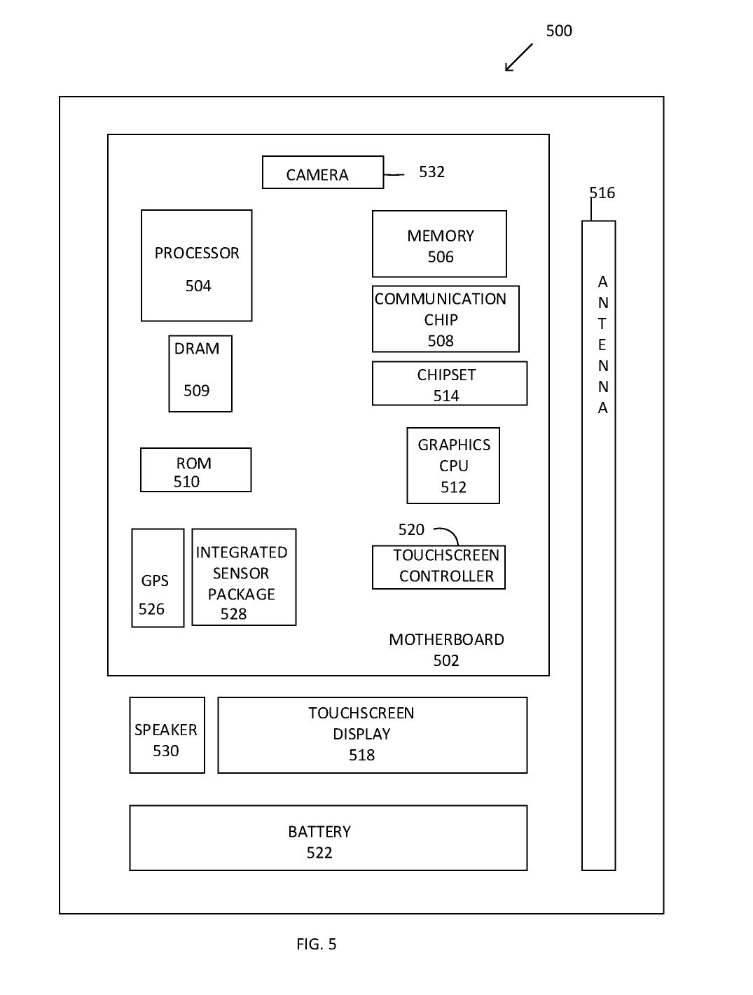

FIG. 5 is a schematic of a computing device 500 that may be implemented incorporating embodiments of the package structures described herein. For example, any suitable ones of the components of the computing device 500 may include, or be included in, a package structure, such as package structure/module 100 of FIG. 1f, for example, or in accordance with any of the embodiments disclosed herein. In an embodiment, the computing device 500 houses a board 502, such as a motherboard 502 for example. The board 502 may include a number of components, including but not limited to a processor 504, an on-die memory 506, and at least one communication chip 508. The processor 504 may be physically and electrically coupled to the board 502. In some implementations the at least one communication chip 508 may be physically and electrically coupled to the board 502. In further implementations, the communication chip 508 is part of the processor 504.

Depending on its applications, computing device 400 may include other components that may or may not be physically and electrically coupled to the board 402, and may or may not be communicatively coupled to each other. These other components include, but are not limited to, volatile memory (e.g., DRAM) 409, non-volatile memory (e.g., ROM) 510, flash memory (not shown), a graphics processor unit (GPU) 412, a chipset 514, an antenna 516, a display 518 such as a touchscreen display, a touchscreen controller 520, a battery 522, an audio codec (not shown), a video codec (not shown), a global positioning system (GPS) device 526, a speaker 530, a camera 532, compact disk (CD) (not shown), digital versatile disk (DVD) (not shown), and so forth). These components may be connected to the system board 502, mounted to the system board, or combined with any of the other components.

The communication chip 508 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 508 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 500 may include a plurality of communication chips 408. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a wearable device, a mobile phone, a desktop computer, a server, a printer, a scanner, a monitor, a set-top box, an entertainment control unit, a digital camera, a portable music player, or a digital video recorder. In further implementations, the computing device 400 may be any other electronic device that processes data.

Embodiments of the package structures described herein may incorporate/may be incorporated within one or more memory chips, controllers, CPUs (Central Processing Unit), microchips or integrated circuits interconnected using a motherboard, an application specific integrated circuit (ASIC), and/or a field programmable gate array (FPGA).

### EXAMPLES

Example 1 is a microelectronic package structure comprising: a shielding structure disposed on a surface of a package structure, wherein the shielding structure comprises: a film; a conductive material disposed on a surface of the film; and a plurality of conductive bars, wherein each individual conductive bar of the plurality of conductive bars is disposed through the film, and at least a portion of the plurality of conductive bars is physically coupled with grounding traces disposed on the surface of the package structure.

Example 2 includes the microelectronic package structure of example 1 wherein the conductive material is disposed on a back surface of the film.

Example 3 includes the microelectronic package structure of example 1 wherein the film comprises a polymeric film.

Example 4 includes the microelectronic package structure of example 1 wherein the package structure comprises a direct chip attach connectivity module.

Example 5 Includes the microelectronic package structure of example 1 wherein the plurality of conductive bars is disposed in a peripheral region of a top surface of the package substrate.

Example 6 includes the microelectronic package structure of example 1 wherein the plurality of conductive bars comprises a portion of a grounding structure.

Example 7 includes the microelectronic package structure of example 7 wherein the shielding structure comprises an EMI shielding structure, wherein a spacing between individual conductive bars is capable of being adjusted to exclude a targeted frequency.

Example 8 includes the microelectronic package structure of example 1 wherein the shielding structure comprises at least one opening, wherein a communication structure is disposed within an individual one of the at least one opening.

Example 9 is a microelectronic package structure comprising a shielding structure disposed on a surface of a package structure, wherein the shielding structure comprises: a film; a conductive material disposed on a surface of the film; and a conductive plate disposed on the conductive material, wherein the conductive plate is disposed within the film, and the conductive plate is physically coupled with grounding traces disposed on the surface of the package structure.

Example 10 includes the microelectronic package structure of example 9 wherein the conductive material comprises a sputtered electromagnetic interference metal.

Example 11 includes the microelectronic package structure of example 9 wherein the shielding structure comprises a Faraday cage.

Example 12 includes the microelectronic package structure of example 9 wherein the conductive material comprises a metallized EMI coating.

Example 13 includes the microelectronic package structure of example 9 wherein the shielding structure is conformal to the surface of the package structure.

Example 14 includes the microelectronic package structure of example 9 wherein the film comprises a polymeric film capable of bonding to surface mount technology (SMT) components disposed on the package structure.

Example 15 includes the microelectronic package structure of example 11 wherein the shielding structure comprises at least one opening, wherein a communication structure is disposed within an individual one of the at least one opening.

Example 16 Includes the microelectronic package structure of example 9, wherein the package structure comprises a direct chip attach wireless connectivity module.

Example 17 is a system comprising: a processor for processing data; a memory for storage of data; a transmitter or receiver for transmission and reception of data; and a module including: a shielding structure disposed on a surface of a package structure, wherein the shielding structure comprises: a film; a conductive material disposed on a surface of the film; and a plurality of conductive bars disposed through the film and in physical contact with the conductive material, and wherein at least a portion of the plurality of conductive bars is physically coupled with grounding traces disposed on the surface of the package structure.

Example 18 includes the system of example 17 wherein the shielding structure comprises an EMI shielding structure.

Example 19 includes the method of example 17 wherein the shielding structure comprises openings, wherein a wireless communication structure is disposed within the openings.

20. The system of claim 19 further comprising wherein the second substrate comprises a low density substrate.

Example 20 includes the system of example 17 further comprising wherein the communication structure is capable of transmitting and receiving wireless communication.

Example 21 includes the system of example 17 further comprising wherein the module comprises a direct chip attach module.

Example 22 includes the system of example 17 further comprising wherein the film comprises a polymeric film.

Example 23 includes the system of example 17 wherein the shielding structure comprises an EMI structure, wherein a spacing between individual conductive bars is capable of being adjusted to exclude a targeted frequency from the module.

Example 24 includes the system of example 17 wherein the film comprises a polymeric film capable of bonding to SMT components disposed on the package structure.

Example 25 includes the system of example 17 wherein the module comprises at least one die, wherein the at least one die comprises a wireless die or a system on a chip.

Example 26 is a method of forming a microelectronic package structure, comprising: forming an EMI coating on a polymer sheet; cutting the polymer sheet to fit individual portions of a multipack; forming metal structures on the EMI coating that extend through the polymeric sheet, and forming connector openings in the EMI coating; and placing the polymer sheet on the multipack.

Example 27 includes the method of forming the microelectronic package structure of example 26 wherein the film comprises a polymeric film.

Example 28 includes the method of forming the microelectronic package structure of example 26 wherein the metal structures comprise at least one of metal bars or metal plates.

Example 29 includes the method of forming the microelectronic package structure of example 26 further comprising wherein an antenna structure disposed on a package structure of the multipack is disposed within the opening.

Example 30 includes the method of forming the microelectronic package structure of example 26 further comprising wherein the metal bars are physically coupled with grounding structures on the package substrate.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus the embodiments are not limited to the structures described herein.

1. A microelectronic package structure comprising:
a shielding structure on a surface of a package structure, wherein the shielding structure comprises:
a film, wherein the film comprises a polymer material;
a conductive material on a surface of the film;
one or more conductive bars, wherein the one or more conductive bars extend at least partially through the film, and at least a portion of the one or more conductive bars is physically coupled with grounding traces on the surface of the package structure; and
one or more communication structures between an edge of the package structure and the one or more conductive bars, wherein the one or more communication structures extend through the conductive material.

2. The microelectronic package structure of claim 1 wherein the conductive material is on a back surface of the film.

3. (canceled)

4. The microelectronic package structure of claim 1 wherein the package structure comprises a connectivity module.

5. The microelectronic package structure of claim 1 wherein the one or more conductive bars is in a peripheral region of a top surface of the microelectronic package substrate.

6. The microelectronic package structure of claim 5 wherein the one or more conductive bars comprises a grounding structure.

7. The microelectronic package structure of claim 1 wherein the shielding structure comprises an electromagnetic interference (EMI) shielding structure, wherein a spacing between individual conductive bars is capable of being adjusted to exclude a targeted frequency.

8. The microelectronic package structure of claim 1 wherein the shielding structure comprises at least one opening, wherein individual ones of the one or more communication structures are within an individual one of the at least one opening.

9. A microelectronic package structure comprising:
a shielding structure on a surface of a package structure, wherein the shielding structure comprises:
a film, wherein the film comprises a polymer material;
a conductive material on a surface of the film; and
a conductive plate on the conductive material, wherein the conductive plate is within the film, and the conductive plate is physically coupled with grounding traces on the surface of the package structure; and
one or more communication structures between an edge of the package structure and the conductive plate, wherein the one or more communication structures extend through the conductive material.

10. The microelectronic package structure of claim 9 wherein the conductive material comprises a sputtered electromagnetic interference metal.

11. (canceled)

12. The microelectronic package structure of claim 9 wherein the conductive material comprises a metallized EMI coating.

13. (canceled)

14. The microelectronic package structure of claim 9 wherein the film is bonded to surface mount technology (SMT) components disposed on the package structure.

15. The microelectronic package structure of claim 9 wherein the shielding structure comprises at least one opening, wherein a individual ones of the one or more communication structures are within an individual one of the at least one opening.

16. The microelectronic package structure of claim 9, wherein the package structure comprises a wireless connectivity module.

17. A system comprising:
a processor to process data;
a memory to store data;
a transmitter to transmit data;
a receiver to receive data; and
a module including:
a shielding structure on a surface of a package structure, wherein the shielding structure comprises:
a film, wherein the film comprises a polymer material;
a conductive material on a surface of the film;
one or more conductive bars extending at least partially through the film and in physical contact with the conductive material, and wherein at least a portion of the one or more conductive bars is physically coupled with grounding traces on the surface of the package structure; and
one or more communication structures between an edge of the package structure and the one or more conductive bars, wherein the one or more communication structures extend through the conductive material.

18. The system of claim 17 wherein the shielding structure comprises an EMI shielding structure.

19. The method of claim 17 wherein the one or more communication structures comprise an antenna.

20. The system of claim 19 further comprising wherein the communication structure is capable of transmitting and receiving wireless communication.

21. The system of claim 17 further comprising wherein the module comprises a wireless connectivity module.

22. (canceled)

23. The system of claim 17 wherein the shielding structure comprises an EMI structure, wherein a spacing between individual conductive bars is capable of being adjusted to exclude a targeted frequency from the module.

24. The system of claim 17 wherein the film comprises a polymeric film bonded to SMT components on the package structure.

25. The system of claim 17 wherein the module comprises at least one die, wherein the at least one die comprises a wireless die or a system on a chip.
